(19) United States
(12) Patent Application Publication
(10) Pub. No.: US 2026/0271737 A1
(43) Pub. Date: Sep. 10, 2026

(54) SEMICONDUCTOR DEVICE

(71) Applicant: SUMITOMO ELECTRIC INDUSTRIES, LTD., Osaka (JP)

(72) Inventors: Hayato SHIMIZU, Osaka (JP); Tatsuya HASHINAGA, Osaka (JP)

(21) Appl. No.: 19/529,563

(22) Filed: Feb. 4, 2026

(30) Foreign Application Priority Data
Mar. 6, 2025 (JP) 2025-035586

(51) Int. Cl. H10W 44/20

(52) U.S. Cl. CPC H10W 44/209; H10W 44/234; H10W 44/241

(57) ABSTRACT

A semiconductor device includes a base having an electrical conductivity, a semiconductor chip mounted on the base, the semiconductor chip including a substrate, an amplifier provided at the substrate and configured to amplify a high frequency signal, a reference potential pad provided on an upper surface of the substrate and electrically connected to a reference potential terminal of the amplifier, and a via wiring line penetrating the substrate and electrically connecting the reference potential pad to the base, a first insulating layer provided over the base so as to cover the semiconductor chip, a first wiring layer provided on the first insulating layer, a first through electrode penetrating the first insulating layer and electrically connecting the first wiring layer to the reference potential pad, and a second through electrode penetrating the first insulating layer and electrically connecting the first wiring layer to the base.

### CROSS REFERENCE TO RELATED APPLICATIONS

This application is based on and claims priority to Japanese Patent Application No. 2025-035586 filed on Mar. 6, 2025, and the entire contents of the Japanese patent application are incorporated herein by reference.

### TECHNICAL FIELD

The present disclosure relates to a semiconductor device.

### BACKGROUND

It is known to provide a circuitry module on a transistor die and to provide a passive electronic component on a surface of the circuit module that is electrically coupled between a gate and a lead or between a drain and a lead (for example, Patent Literature 1: Japanese Unexamined Patent Application Publication No. 2023-159434).

### SUMMARY

A semiconductor device according to an embodiment of the present disclosure includes a base having an electrical conductivity, a semiconductor chip mounted on the base, the semiconductor chip including a substrate, an amplifier provided at the substrate and configured to amplify a high frequency signal, a reference potential pad provided on an upper surface of the substrate and electrically connected to a reference potential terminal of the amplifier, and a via wiring line penetrating the substrate and electrically connecting the reference potential pad to the base, a first insulating layer provided over the base so as to cover the semiconductor chip, a first wiring layer provided on the first insulating layer, a first through electrode penetrating the first insulating layer and electrically connecting the first wiring layer to the reference potential pad, and a second through electrode penetrating the first insulating layer and electrically connecting the first wiring layer to the base.

### BRIEF DESCRIPTION OF THE DRAWINGS

FIG. 1 is a cross-sectional view of a semiconductor device according to a first embodiment.

FIG. 2 is a plan view of a periphery of a semiconductor chip of the semiconductor device according to the first embodiment.

FIG. 3 is a plan view of a periphery of the semiconductor chip of the semiconductor device according to the first embodiment.

FIG. 4 is a cross-sectional view taken along line A-A in FIGS. 2 and 3.

FIG. 5 is a cross-sectional view taken along line B-B in FIGS. 2 and 3.

FIG. 6 is a perspective view of a periphery of the semiconductor chip of the semiconductor device according to the first embodiment.

FIG. 7 is a circuit diagram illustrating an equivalent circuit of the semiconductor device according to the first embodiment.

FIG. 8 is a plan view of a semiconductor device according to a first comparative embodiment.

FIG. 9 is a plan view of a semiconductor device according to a second comparative embodiment.

FIG. 10 is a cross-sectional view taken along line A-A of FIG. 9.

FIG. 11 is a circuit diagram illustrating an equivalent circuit of the semiconductor device according to the second comparative embodiment.

FIG. 12 is a schematic diagram illustrating the maximum gain with respect to a frequency in the first comparative embodiment and the second comparative embodiment.

FIG. 13 is a schematic diagram indicating a corner frequency fk and the maximum gain at fk.

FIG. 14 is a cross-sectional view of a semiconductor device according to a third comparative embodiment.

FIG. 15 is a circuit diagram illustrating an equivalent circuit of the semiconductor device according to the third comparative embodiment.

FIG. 16 is a cross-sectional view of a semiconductor device according to a fourth comparative embodiment.

FIG. 17 is a circuit diagram illustrating an equivalent circuit of the semiconductor device according to the fourth comparative embodiment.

FIG. 18 is a cross-sectional view of a semiconductor device according to a second embodiment.

FIG. 19 is a cross-sectional view taken along line A-A of FIG. 18.

FIG. 20 is a circuit diagram illustrating an equivalent circuit of the semiconductor device according to the second embodiment.

FIG. 21 is a schematic diagram illustrating the maximum gain with respect to a frequency in embodiments and comparative embodiments.

FIG. 22 is a cross-sectional view of a semiconductor device according to a third embodiment.

FIG. 23 is a cross-sectional view of a semiconductor device according to a fifth comparative embodiment.

### DETAILED DESCRIPTION

A reference potential terminal of a semiconductor chip such as a transistor die may be connected to a ground through a via penetrating the semiconductor chip. However, by connecting the reference potential terminal to the ground through the via, an inductance component and a resistance component increase. This deteriorates high-frequency characteristics such as gain.

It is desired to provide a semiconductor device that can improve high-frequency characteristics.

According to the present disclosure, a semiconductor device that can improve high-frequency characteristics can be provided.

### Description of Embodiments of Present Disclosure

First, embodiments of the present disclosure will be listed and described.
(1) A semiconductor device according to an embodiment of the present disclosure includes a base having an electrical conductivity, a semiconductor chip mounted on the base, the semiconductor chip including a substrate, an amplifier provided at the substrate and configured to amplify a high frequency signal, a reference potential pad provided on an upper surface of the substrate and electrically connected to a reference potential terminal of the amplifier, and a via wiring line penetrating the substrate and electrically connecting the reference potential pad to the base, a first insulating layer provided over the base so as to cover the semiconductor chip, a first wiring layer provided on the first insulating layer, a first through electrode penetrating the first insulating layer and electrically connecting the first wiring layer to the reference potential pad, and a second through electrode penetrating the first insulating layer and electrically connecting the first wiring layer to the base. This can reduce the inductance and resistance connected to the reference potential, thereby improving high-frequency characteristics.
(2) In the above (1), the semiconductor chip may include an input pad electrically connected to an input terminal of the amplifier and provided on the upper surface of the substrate, and an output pad electrically connected to an output terminal of the amplifier and provided on the upper surface of the substrate. The semiconductor device may include a second wiring layer provided on the first insulating layer, a third wiring layer provided on the first insulating layer, a third through electrode penetrating the first insulating layer and electrically connecting the second wiring layer to the input pad, and a fourth through electrode penetrating the first insulating layer and electrically connecting the third wiring layer to the output pad. This simplifies the manufacturing process of forming the first wiring layer.
(3) In the above (2), the semiconductor device may further include a fourth wiring layer electrically connected to the first wiring layer and provided on the first insulating layer between the second wiring layer and the third wiring layer. This can reduce the feedback capacitance, thereby improving the high-frequency characteristics.
(4) In the above (3), a distance between the fourth wiring layer and the second wiring layer may be shorter than a distance between the fourth wiring layer and the third wiring layer. This can improve the high-frequency characteristics.
(5) In the above (3) or (4), an arrangement direction may be a direction from the second wiring layer toward the third wiring layer. A distance by which the first wiring layer protrudes from the fourth wiring layer in the arrangement direction may be shorter than a distance by which the first wiring layer protrudes from the fourth wiring layer in a direction opposite to the arrangement direction. This can improve the high-frequency characteristics.
(6) In any one of the above (2) to (5), a plurality of the reference potential pads, a plurality of the first wiring layers, a plurality of the first through electrodes, and a plurality of the second through electrodes may be each provided so as to sandwich the amplifier. This can improve the high-frequency characteristics.
(7) In any one of the above (1) to (6), the amplifier may include a transistor. The reference potential terminal may be a source of the transistor. The input terminal may be a gate of the transistor. The output terminal may be a drain of the transistor. This can improve the high-frequency characteristics.
(8) In any one of the above (1) to (7), a shortest distance between the first through electrode and the second through electrode may be shorter than a minimum width of the semiconductor chip. This can improve the high-frequency characteristics.
(9) In any one of the above (1) to (8), the base may have a lower surface that is a reference potential surface to which a reference potential is supplied. This can improve the high-frequency characteristics.
(10) In any one of the above (1) to (8), the semiconductor device may further include a second insulating layer provided over the first insulating layer so as to cover the first wiring layer, a metal layer provided on the second insulating layer, and a fifth through electrode penetrating the second insulating layer and electrically connecting the metal layer to the first wiring layer. This can improve the high-frequency characteristics.
(11) In the above (10), the metal layer may have an upper surface that is a reference potential surface to which a reference potential is supplied. This can improve the high-frequency characteristics.

### Details of Embodiments of Present Disclosure

Specific examples of a semiconductor device according to embodiments of the present disclosure will be described below with reference to the drawings. The present disclosure is not limited to these examples, but is defined by the scope of the claims, and is intended to include all modifications within the meaning and scope equivalent to the scope of the claims.

### First Embodiment

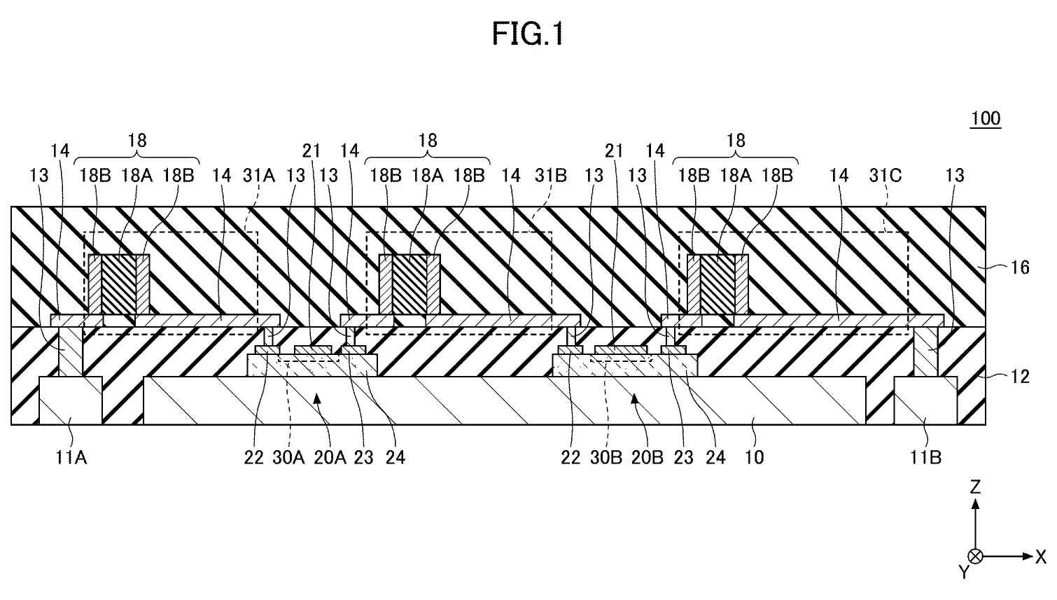

FIG. 1 is a cross-sectional view of a semiconductor device according to a first embodiment. A thickness direction of a base 10 is defined as a Z direction, an arrangement direction of an input pad 22 and an output pad 23 in a semiconductor chip 20 is defined as an X direction, and a direction orthogonal to the X direction and the Z direction is defined as a Y direction.

As illustrated in FIG. 1, a semiconductor device 100 of the first embodiment includes the base 10, terminals 11A and 11B, insulating layers 12 and 16, a through electrode 13, a wiring layer 14, semiconductor chips 20A and 20B, and an electronic component 18.

The base 10 and the terminals 11A and 11B are conductors having electrical conductivity. The semiconductor chips 20A and 20B are mounted on the base 10. A reference potential such as a ground potential is supplied to the base 10. The semiconductor chips 20A and 20B include amplifiers 30A and 30B, respectively. Each of the semiconductor chips 20A and 20B includes a substrate 24, a reference potential pad 21, the input pad 22, and the output pad 23. The reference potential pad 21, the input pad 22, and the output pad 23 are provided on an upper surface of the substrate 24.

Each of the base 10 and the terminals 11A and 11B is a metal plate such as a copper plate, and is, for example, a lead frame. The insulating layer 12 (first insulating layer) is provided over the base 10 and the terminals 11A and 11B so as to cover the semiconductor chips 20A and 20B. The through electrode 13 penetrates the insulating layer 12 and is electrically connected to the terminals 11A and 11B, the input pad 22, and the output pad 23. The wiring layer 14 is provided on the insulating layer 12. A part of the wiring layer 14 functions as a signal line of a microstrip line for transmitting a high frequency signal. The wiring layer 14 is electrically connected to the terminals 11A and 11B, the input pad 22, and the output pad 23 via the through electrode 13. The electronic component 18 is mounted on the wiring layer 14. The electronic component 18 includes a main body 18A and an electrode 18B. The electrode 18B is provided on a surface of the main body 18A. The electrode 18B is bonded to the wiring layer 14 using, for example, a conductive bonding layer. The electronic component 18 is, for example, a discrete passive component, and is a chip capacitor, a chip inductor, or a chip resistor. The insulating layer 16 is provided over the insulating layer 12 so as to cover the electronic component 18 and the wiring layer 14. Each of the insulating layers 12 and 16 is made of resin such as epoxy resin. Each of the through electrode 13 and the wiring layer 14 is, for example, a metal layer such as a copper layer.

A passive circuit 31A includes the wiring layer 14 and the electronic component 18 connected between the terminal 11A and the semiconductor chip 20A. A passive circuit 31B includes the wiring layer 14 and the electronic component 18 connected between the semiconductor chips 20A and 20B. A passive circuit 31C includes the wiring layer 14 and the electronic component 18 connected between the semiconductor chip 20B and the terminal 11B. Each of the passive circuits 31A, 31B, and 31C includes, for example, an impedance matching circuit. The passive circuit 31A matches an impedance seen from the terminal 11A to the passive circuit 31A and an impedance seen from the passive circuit 31A to the amplifier 30A. The passive circuit 31B matches an impedance seen from the amplifier 30A to the passive circuit 31B and an impedance seen from the passive circuit 31B to the amplifier 30B. The passive circuit 31C matches an impedance seen from the amplifier 30B to the passive circuit 31C and an impedance seen from the passive circuit 31C to the terminal 11B.

A high frequency signal is input to the terminal 11A. When the semiconductor device 100 is used in a base station for mobile communication, the frequency of the high frequency signal is, for example, 0.5 GHz to 20 GHz. The high frequency signal is input to the input pad 22 of the semiconductor chip 20A via the passive circuit 31A. The amplifier 30A amplifies the high frequency signal input to the input pad 22 and outputs the amplified high frequency signal to the output pad 23. The high frequency signal amplified by the amplifier 30A is input to the input pad 22 of the semiconductor chip 20B via the passive circuit 31B. The amplifier 30B amplifies the high frequency signal input to the input pad 22 and outputs the amplified high frequency signal to the output pad 23. The high frequency signal amplified by the amplifier 30B is output from the terminal 11B via the passive circuit 31C.

Although the example in which the number of the amplifiers 30A and 30B is two has been described in FIG. 1, the number of the amplifiers may be one or three or more.

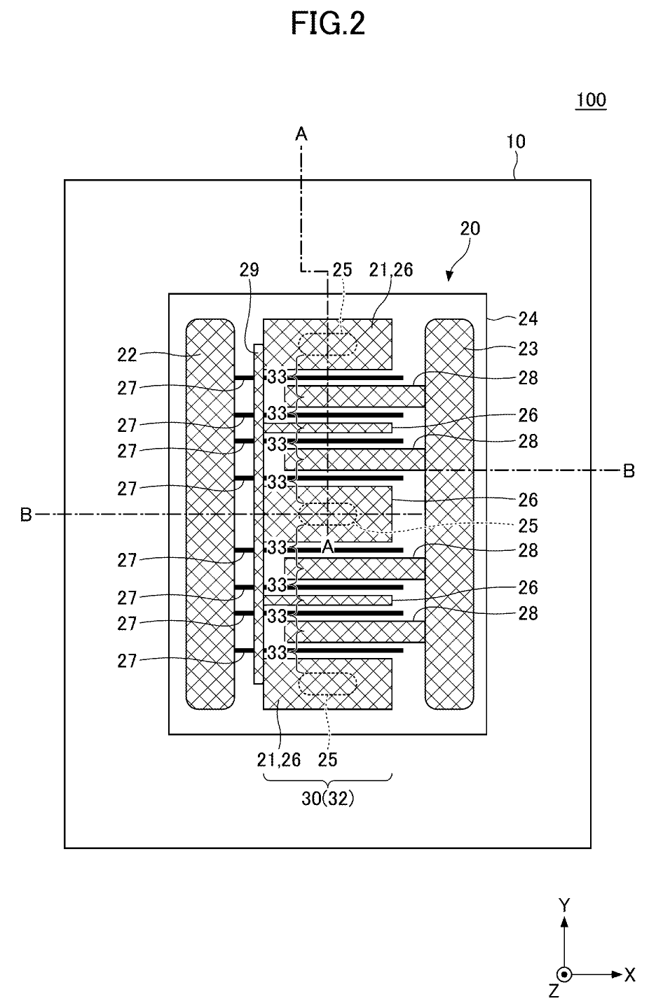

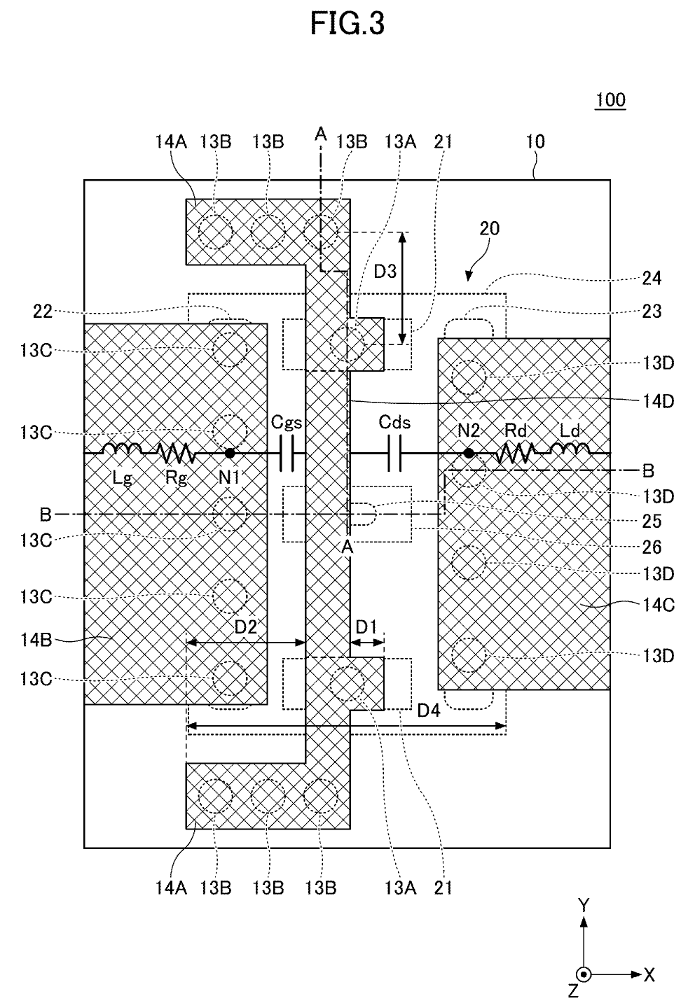

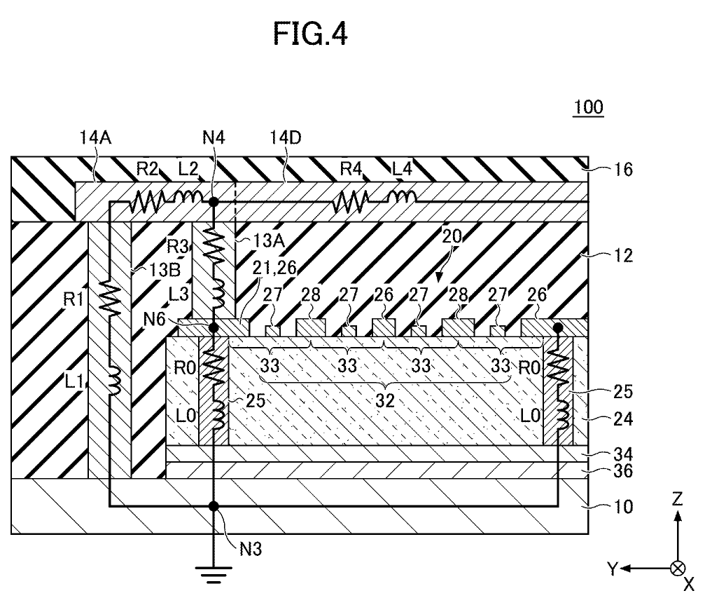

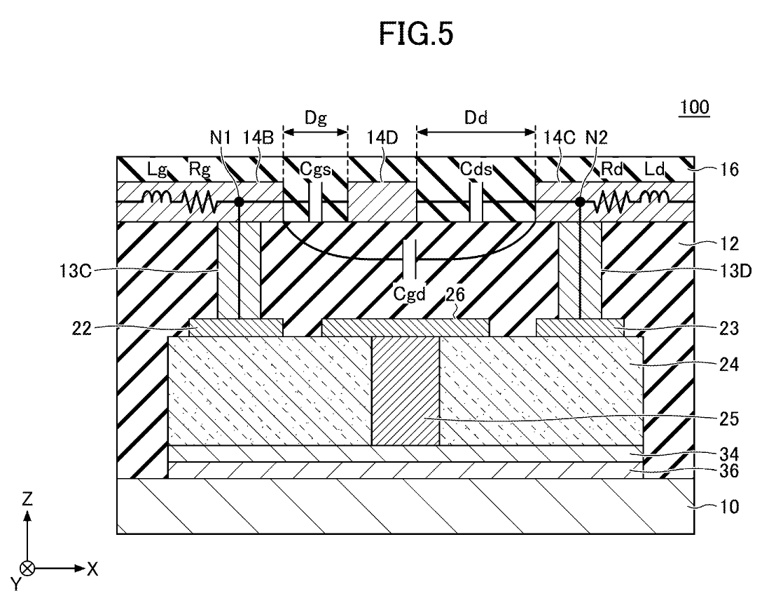

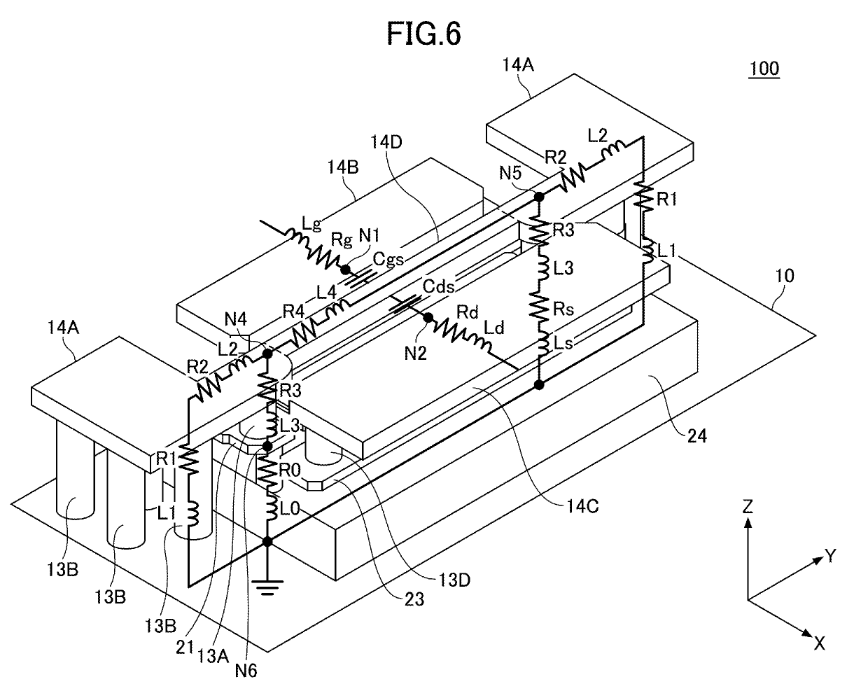

FIGS. 2 and 3 are plan views of a periphery of the semiconductor chip of the semiconductor device according to the first embodiment. FIG. 2 mainly illustrates the semiconductor chip 20, and FIG. 3 mainly illustrates the wiring layer 14. FIG. 4 is a cross-sectional view taken along line A-A in FIGS. 2 and 3. FIG. 5 is a cross-sectional view taken along line B-B in FIGS. 2 and 3. FIG. 6 is a perspective view of a periphery of the semiconductor chip of the semiconductor device according to the first embodiment. The semiconductor chips 20A and 20B in FIG. 1 will be described as the semiconductor chip 20.

As illustrated in FIGS. 2, 4 and 5, the semiconductor chip 20 includes the substrate 24, the reference potential pad 21, the input pad 22, the output pad 23, a via wiring line 25, an amplifier 30, and an electrode 34. The reference potential pad 21, the input pad 22, and the output pad 23 are provided on the upper surface of the substrate 24. The electrode 34 is provided on the entire lower surface of the substrate 24. The via wiring line 25 penetrates the substrate 24 and electrically connects the reference potential pad 21 to the electrode 34, thereby forming an electrical short. The electrode 34 is bonded to the base 10 by a bonding member 36 having electrical conductivity. Thus, the via wiring line 25 electrically connects the reference potential pad 21 to the base 10.

The amplifier 30 includes a transistor 32. The transistor 32 includes a plurality of source electrodes 26, a plurality of gate electrodes 27, and a plurality of drain electrodes 28. The plurality of source electrodes 26, the plurality of gate electrodes 27, and the plurality of drain electrodes 28 are finger-shaped and extend in the X direction. The plurality of source electrodes 26 and the plurality of drain electrodes 28 are alternately provided in the Y direction. One source electrode 26 and one drain electrode 28 sandwich one gate electrode 27 in the Y direction. A plurality of unit FETs 33 are arranged in the Y direction, and each of the plurality of unit FETs 33 includes one source electrode 26, one drain electrode 28, and one gate electrode 27.

The plurality of gate electrodes 27 are connected to the input pad 22 at a negative end in the X direction. The plurality of drain electrodes 28 are connected to the output pad 23 at a positive end in the X direction. The source electrode 26 to which the via wiring line 25 is connected among the source electrodes 26 serves as the reference potential pad 21. A source wiring line 29 crosses the gate electrode 27 in a non-contact manner, and electrically connects the reference potential pad 21 to the source electrode 26 to which the via wiring line 25 is not connected, thereby forming an electrical short.

A source potential (for example, a reference potential) is supplied from the base 10 to the reference potential pad 21 via the bonding member 36, the electrode 34, and the via wiring line 25. Further, the source potential is supplied from the reference potential pad 21 to the source electrode 26 via the source wiring line 29. A gate potential (for example, a high frequency signal and a gate bias voltage) is supplied from the input pad 22 to the gate electrode 27. A drain potential (for example, a drain bias voltage) is supplied from the output pad 23 to the drain electrode 28. The amplified high frequency signal is output from the drain electrode 28 to the output pad 23.

When the transistor 32 is a gallium nitride high electron mobility transistor (GaN HEMT), the substrate 24 includes, for example, a silicon carbide substrate or a sapphire substrate, a gallium nitride channel layer, and an aluminum gallium nitride barrier layer. When the transistor 32 is a laterally diffused metal oxide semiconductor (LDMOS), the substrate 24 is a silicon substrate.

The source electrode 26 and the drain electrode 28 are each, for example, titanium films and aluminum films from the substrate 24. The gate electrode 27 is, for example, a nickel film and a gold film from the substrate 24. The reference potential pad 21, the input pad 22, the output pad 23, the via wiring line 25, and the electrode 34 are each a metal layer, such as a gold layer, a copper layer, or an aluminum layer. The bonding member 36 is a metal layer formed by sintering a conductive paste such as a silver paste.

As illustrated in FIGS. 3 to 6, the through electrodes 13A to 13D penetrate the insulating layer 12. The wiring layers 14A to 14D are provided on the insulating layer 12. The through electrode 13A electrically connects the wiring layer 14A to the reference potential pad 21, thereby forming an electrical short. The through electrode 13B electrically connects the wiring layer 14A to the base 10, thereby forming an electrical short. The through electrode 13C electrically connects the wiring layer 14B to the input pad 22, thereby forming an electrical short. The through electrode 13D electrically connects the wiring layer 14C to the output pad 23, thereby forming an electrical short. The wiring layer 14D is provided between the wiring layers 14B and 14C, and is electrically connected to the wiring layer 14A, thereby forming an electrical short.

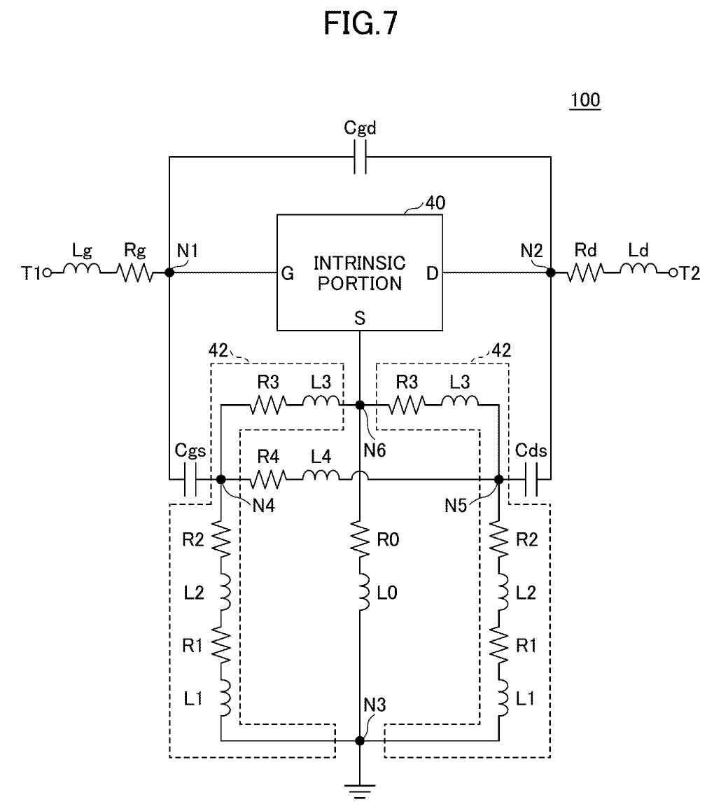

FIG. 7 is a circuit diagram illustrating an equivalent circuit of the semiconductor device according to the first embodiment. In FIG. 7, the transistor 32 is set to an intrinsic portion 40. The intrinsic portion 40 has a source S, a gate G, and a drain D. A terminal T1 is a terminal to which the high frequency signal is input. A terminal T2 is a terminal from which the high frequency signal is output. A gate inductance Lg and a gate resistance Rg are connected in series between the terminal T1 and the gate G. The drain inductance Ld and a drain resistance Rd are connected in series between the terminal T2 and the drain D. An inductor L0 and a resistor R0 are connected in series between the ground and the source S.

A gate-drain capacitance Cgd is connected between nodes N1 and N2. The node N1 is a node between the gate resistance Rg and the gate G. The node N2 is a node between the drain resistance Rd and the drain D. A gate-source capacitance Cgs is connected between the nodes N1 and N4. A drain-source capacitance Cds is connected between the nodes N2 and N5. Inductors L1 and L2 and resistors R1 and R2 are connected in series between the node N4 and N3, and other inductors L1 and L2 and resistors R1 and R2 are connected in series between the nodes N5 and N3. The node N3 is a node between the ground and the inductor L0. An inductor L3 and a resistor R3 are connected in series between the nodes N4 and N6. Another inductor L3 and resistor R3 are connected in series between the nodes N5 and N6. The node N6 is a node between the source S and the resistor R0, and the inductor L4 and the resistor R4 are connected in series between the nodes N4 and N5.

As illustrated in FIGS. 3 to 6, the gate inductance Lg and the gate resistance Rg mainly correspond to an inductance component and a resistance component in the wiring layer 14B, respectively. The drain inductance Ld and the drain resistance Rd mainly correspond to an inductance component and a resistance component in the wiring layer 14C, respectively. The inductor L0 and the resistor R0 mainly correspond to an inductance component and a resistance component in the via wiring line 25, respectively.

The gate-drain capacitance Cgd mainly corresponds to a capacitance component between the wiring layers 14B and 14C. The gate-source capacitance Cgs mainly corresponds to a capacitance component between the wiring layers 14B and 14D. The drain-source capacitance Cds mainly corresponds to a capacitance component between the wiring layers 14C and 14D. The inductor L1 and the resistor R1 mainly correspond to an inductance component and a resistance component in the through electrode 13B, respectively. The inductor L2 and the resistor R2 mainly correspond to an inductance component and a resistance component in the wiring layer 14A, respectively. The inductor L3 and the resistor R3 mainly correspond to an inductance component and a resistance component in the through electrode 13A, respectively. The inductor L4 and the resistor R4 mainly correspond to an inductance component and a resistance component in the wiring layer 14D, respectively.

### First Comparative Embodiment

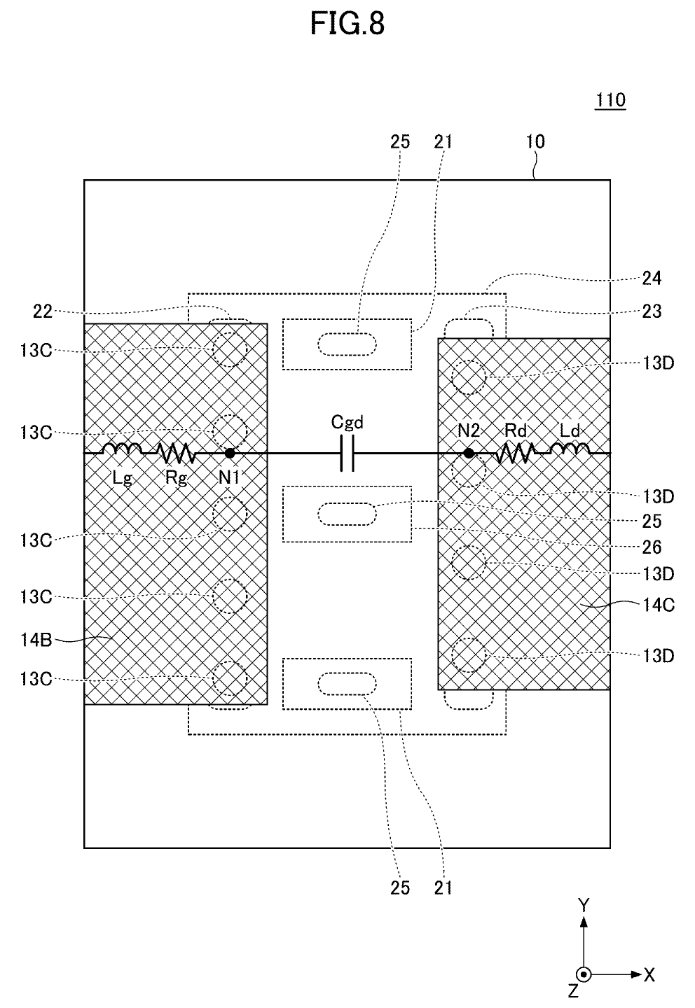

FIG. 8 is a plan view of a semiconductor device according to a first comparative embodiment. As illustrated in FIG. 8, in a semiconductor device 110 of the first comparative embodiment, the wiring layers 14A and 14D and the through electrodes 13A and 13B are omitted. The other configurations are the same as those of the first embodiment, and the description thereof will be omitted.

In the first comparative embodiment, the gate-drain capacitance Cgd is generated between the wiring layers 14B and 14C. The gate-drain capacitance Cgd is a feedback capacitance of the amplifier 30. As the gate-drain capacitance Cgd increases, the gain and efficiency decrease. In particular, as the center frequency of the operating band increases, a length of the gate electrode 27 in the X direction is shortened to reduce the resistance caused by the gate electrode in order to improve the gain. Thus, a distance between the input pad 22 and the output pad 23 is shortened. Due to this, a distance between the wiring layers 14B and 14C is also shortened. This increases the gate-drain capacitance Cgd.

### Second Comparative Embodiment

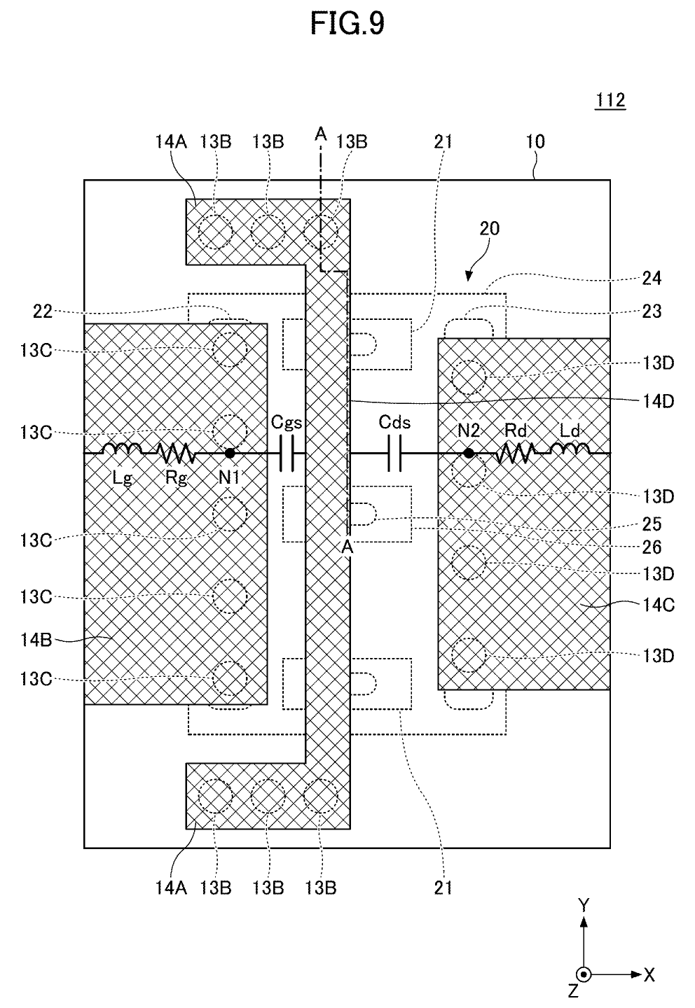

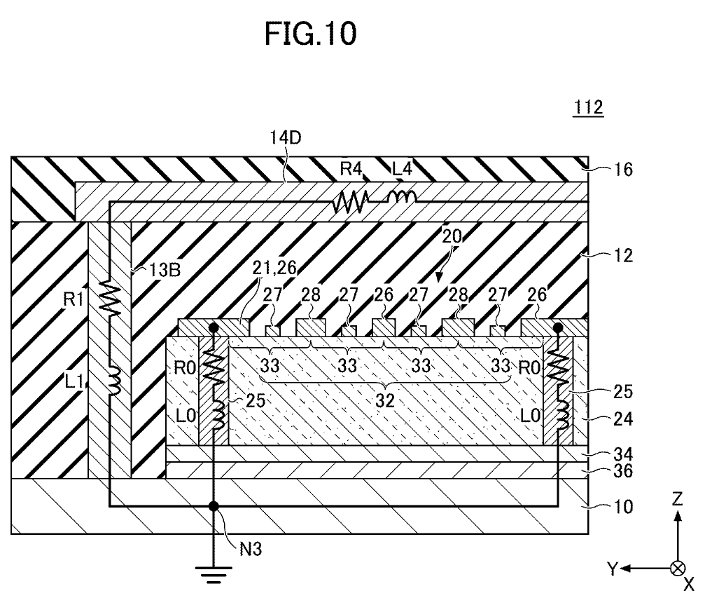

FIG. 9 is a plan view of a semiconductor device according to a second comparative embodiment. FIG. 10 is a cross-sectional view taken along line A-A of FIG. 9. In the second comparative embodiment, the wiring layer 14D is provided between the wiring layer 14B and the wiring layer 14C. The wiring layer 14D is electrically connected to the base 10 via the through electrode 13B. The other configurations are the same as those of the first comparative embodiment, and the description thereof will be omitted. In the second comparative embodiment, the wiring layer 14D electrically connected to the base 10 is disposed between the wiring layers 14B and 14C. This reduces the gate-drain capacitance Cgd.

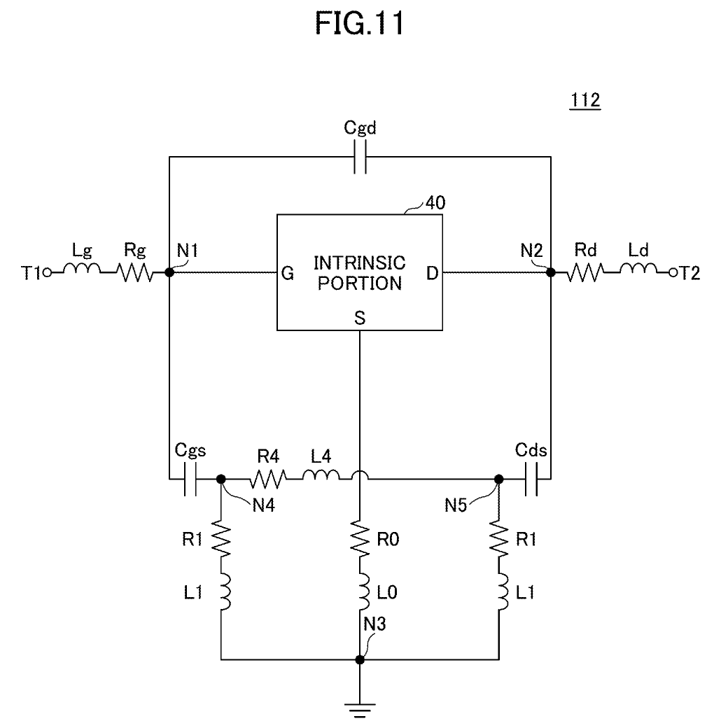

FIG. 11 is a circuit diagram illustrating an equivalent circuit of the semiconductor device according to the second comparative embodiment. As compared with FIG. 7 of the first embodiment, the inductors L2 and L3 and the resistors R2 and R3 are not omitted.

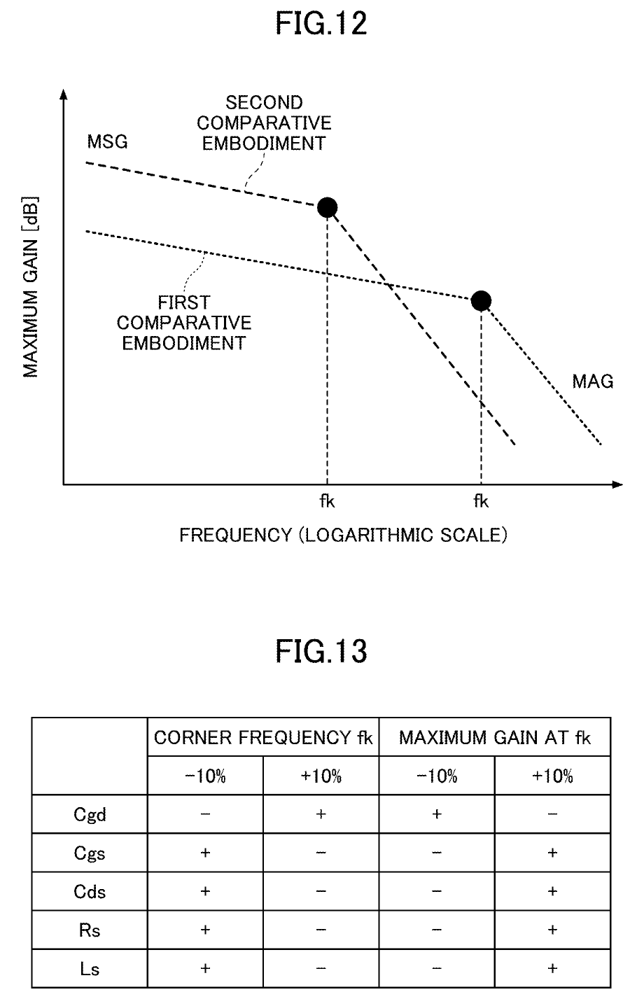

FIG. 12 is a schematic diagram illustrating the maximum gain with respect to a frequency in the first comparative embodiment and the second comparative embodiment. The frequency on the horizontal axis is displayed logarithmically. As illustrated in FIG. 12, in both the first and second comparative embodiments, the maximum gain is the maximum stable gain (MSG) in a region where the frequency is low. In a region where the frequency is high, the maximum gain is the maximum available power gain (MAG). A corner frequency of MSG and MAG is fk. MAG has a larger reduction rate of gain with respect to frequency than MSG. The corner frequency fk is, for example, a frequency of 1 GHz to 10 GHz.

In the second comparative embodiment, MSG is improved compared to the first comparative embodiment. However, the corner frequency fk decreases. As a result, the maximum gain in the region where the frequency is high is smaller than that in the first comparative embodiment.

FIG. 13 is a schematic diagram indicating the change in the corner frequency fk and the maximum gain at fk with respect to the capacitance, resistance, and inductance. In FIG. 13, the item "-10%" indicates the change in the corner frequency fk and the maximum gain at fk when the gate-drain capacitance Cgd, the gate-source capacitance Cgs, the drain-source capacitance Cds, a source resistance Rs, and a source inductance Ls each decrease by 10%. The item “MAXIMUM GAIN AT fk” is the maximum gain at fk. The item "+10%" indicates the change in the corner frequency fk and the maximum gain at fk when the gate-drain capacitance Cgd, the gate-source capacitance Cgs, the drain-source capacitance Cds, the source resistance Rs, and the source inductance Ls each increase by 10%. The "+" and "-" indicate that the corner frequency fk and the maximum gain at fk increase and decrease, respectively.

As indicated in FIG. 13, as the gate-drain capacitance Cgd decreases, the maximum gain at fk increases and the corner frequency fk decreases. As the gate-drain capacitance Cgd increases, the corner frequency fk increases and the maximum gain at fk decreases. Thus, in FIG. 12, it is considered that, in the second comparative embodiment, MSG increases, but the corner frequency fk decreases as compared with the first comparative embodiment.

As the gate-source capacitance Cgs, the drain-source capacitance Cds, the source resistance Rs, and the source inductance Ls decrease, the corner frequency fk increases and the maximum gain at fk decreases. As the gate-source capacitance Cgs, the drain-source capacitance Cds, the source resistance Rs, and the source inductance Ls increase, the corner frequency fk decreases, and the maximum gain at fk increases. When the wiring layer 14D is provided to reduce the gate-drain capacitance Cgd as in the second comparative embodiment, the gate-source capacitance Cgs and the drain-source capacitance Cds increase, and the corner frequency fk decreases. It is difficult to reduce the gate-source capacitance Cgs and the drain-source capacitance Cds. Thus, it is conceivable to reduce the source inductance Ls and the source resistance Rs to increase the corner frequency fk. The source inductance Ls affects the high-frequency characteristics more than the source resistance Rs.

### Third Comparative Embodiment

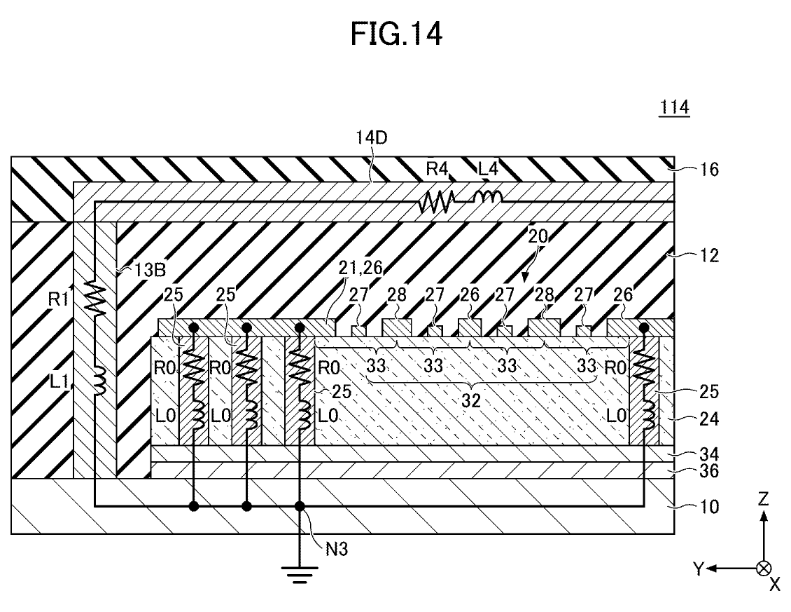

FIG. 14 is a cross-sectional view of a semiconductor device according to a third comparative embodiment. As illustrated in FIG. 14, in a semiconductor device 114 of the third comparative embodiment, the plurality of via wiring lines 25 are connected in parallel between one reference potential pad 21 and the base 10. The other configurations are the same as those of the second comparative embodiment, and the description thereof will be omitted.

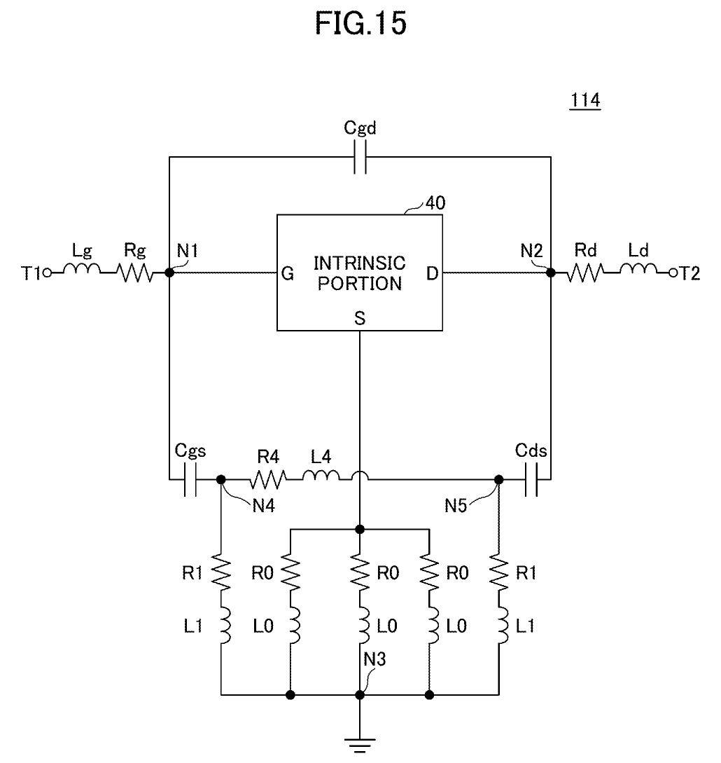

FIG. 15 is a circuit diagram illustrating an equivalent circuit of the semiconductor device according to the third comparative embodiment. As compared with FIG. 11 of the second comparative embodiment, a plurality of paths are connected in parallel between the source S and the node N3. In each path, the inductor L0 and the resistor R0 are connected in series.

In the semiconductor device 114 of the third comparative embodiment, the inductor L0 and the resistor R0 connected in series between the source S and the ground are connected in parallel by providing the plurality of via wiring lines 25 in parallel. Thus, the source inductance Ls and the source resistance Rs are reduced. Thus, the corner frequency fk can be increased. However, when the plurality of via wiring lines 25 are provided in parallel, the chip size of the semiconductor chip 20 increases as illustrated in FIG. 14. The semiconductor chip 20 is manufactured through a complicated manufacturing process, and the chip area unit price is high. Thus, as the chip size of the semiconductor chip 20 increases, the cost of the semiconductor device 114 increases.

### Fourth Comparative Embodiment

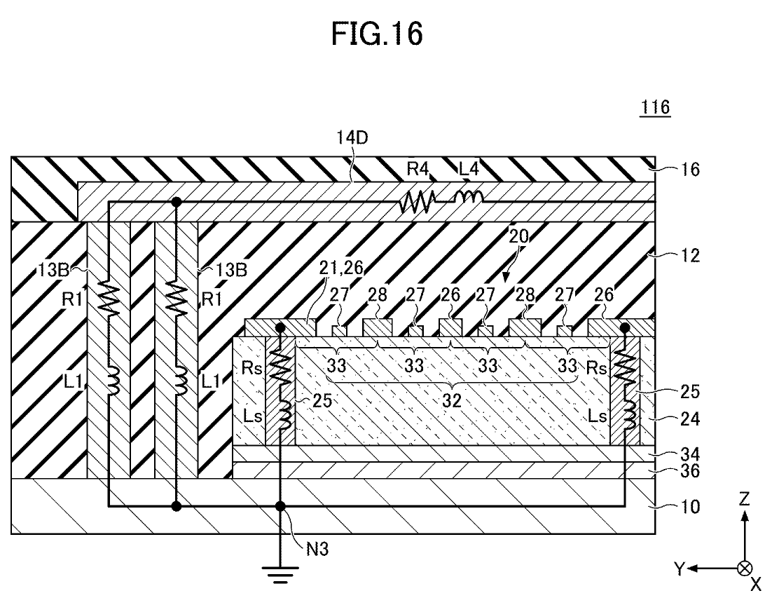

FIG. 16 is a cross-sectional view of a semiconductor device according to a fourth comparative embodiment. As illustrated in FIG. 16, in a semiconductor device 116 of the fourth comparative embodiment, a plurality of through electrodes 13B are connected in parallel between the wiring layer 14D and the base 10. The other configurations are the same as those of the second comparative embodiment, and the description thereof will be omitted.

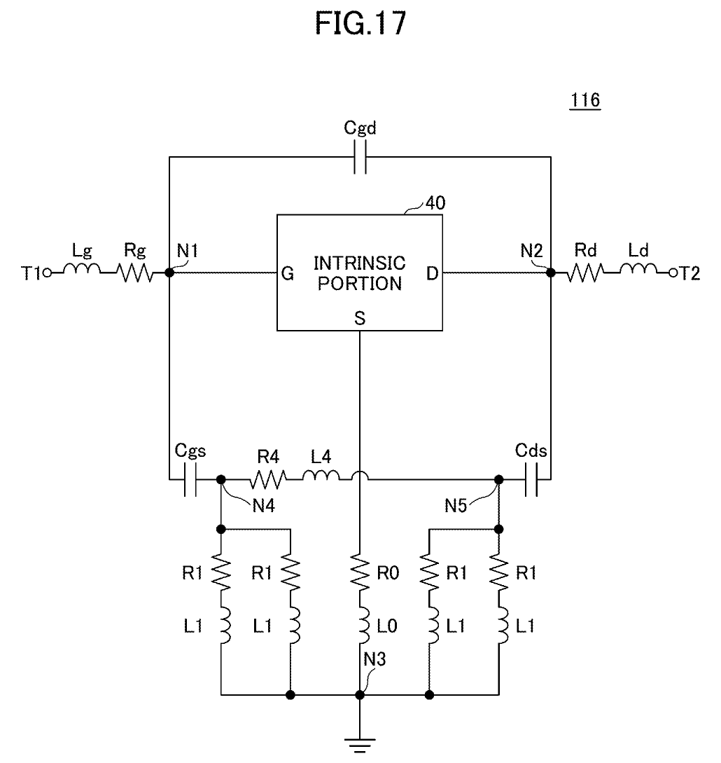

FIG. 17 is a circuit diagram illustrating an equivalent circuit of the semiconductor device according to the fourth comparative embodiment. As illustrated in FIG. 17, a plurality of paths are connected in parallel between the nodes N4 and N3, as compared with FIG. 11 of the second comparative embodiment. In each path, the inductor L1 and the resistor R1 are connected in series.

In the semiconductor device 116 of the fourth comparative embodiment, since the plurality of via wiring lines 25 are not provided in parallel as in the semiconductor device 114 of the third comparative embodiment, the chip size of the semiconductor chip 20 is the same as that of the second comparative embodiment. As illustrated in FIG. 17, since the plurality of paths are provided between the nodes N4 and N3, the inductance and resistance between the nodes N4 and N3 decrease. However, the source inductance Ls and the source resistance Rs between the source S and the ground are the same as those in the second comparative embodiment. Thus, the corner frequency fk cannot be increased.

### Description of First Embodiment

In the first embodiment, as illustrated in FIGS. 2 to 6, the reference potential pad 21 is electrically connected to the source electrode 26 of the transistor 32. The source electrode 26 corresponds to a reference potential terminal of the amplifier 30. The through electrode 13A (first through electrode) penetrates the insulating layer 12 and electrically connects the wiring layer 14A (first wiring layer) to the reference potential pad 21. The through electrode 13B (second through electrode) penetrates the insulating layer 12 and electrically connects the wiring layer 14A to the base 10. As a result, as illustrated in FIG. 7, a path 42 is connected in parallel with the inductor L0 and the resistor R0 between the source S and the ground. The path 42 connects the node N6 to the node N3. The path 42 includes the inductors L1, L2, L3 and the resistors R1, R2, and R3, connected in series. That is, the reference potential pad 21 is electrically connected to the base 10 with a path from the reference potential pad 21 to the through electrode 13A, the wiring layer 14A, and the through electrode 13B in addition to a path from the reference potential pad 21 to the base 10 via the via wiring line 25. This can reduce the source inductance Ls and the source resistance Rs, and thus can increase the corner frequency fk. Thus, the maximum gain in the high-frequency region can be improved, and the high-frequency characteristics can be improved.

As illustrated in FIGS. 2 to 6, the input pad 22 is electrically connected to the gate electrode 27 of the transistor 32. The output pad 23 is electrically connected to the drain electrode 28 of the transistor 32. The gate electrode 27 corresponds to an input terminal of the amplifier 30. The drain electrode 28 corresponds to an output terminal of the amplifier 30. The wiring layer 14B (second wiring layer) and the wiring layer 14C (third wiring layer) are provided on the insulating layer 12. The through electrode 13C (third through electrode) electrically connects the wiring layer 14B to the input pad 22. The through electrode 13D (fourth through electrode) electrically connects the wiring layer 14C to the output pad 23. In this manner, the wiring layer of the same level as the wiring layers 14B and 14C can be used for the wiring layer 14A. This simplifies the manufacturing process of forming the wiring layer 14A.

By providing the wiring layers 14B and 14C, the gate-drain capacitance Cgd is generated between the wiring layers 14B and 14C. Thus, the high-frequency characteristics are degraded. Thus, the wiring layer 14D (fourth wiring layer) is electrically connected to the wiring layer 14A and is provided between the wiring layers 14B and 14C. This can reduce the gate-drain capacitance Cgd, thereby improving the high-frequency characteristics such as the maximum gain.

The drain-source capacitance Cds affects the corner frequency fk more than the gate-source capacitance Cgs. Here, as illustrated in FIG. 5, when the distance between the wiring layers 14D and 14B is Dg and the distance between the wiring layers 14D and 14C is Dd, the distance Dg is made shorter than Dd. This increases the gate-source capacitance Cgs and reduces the drain-source capacitance Cds. Thus, the corner frequency fk can be increased, thereby improving the high-frequency characteristics. The distance Dg can be less than the distance Dd, and can be 0.8 times the distance Dd or less. The distance Dg and the distance Dd may be equal to each other.

As illustrated in FIG. 3, when the positive X direction is an arrangement direction from the wiring layer 14B toward the wiring layer 14C, a distance by which the wiring layer 14A protrudes from the wiring layer 14D in the positive X direction is defined as D1, and a distance by which the wiring layer 14A protrudes from the wiring layer 14D in the negative X direction is defined as D2. The distance D1 is shorter than the distance D2. This increases the gate-source capacitance Cgs and reduces the drain-source capacitance Cds. Thus, the corner frequency fk can be increased, thereby improving the high-frequency characteristics. The distance D1 may be 0.8 times the distance D2 or less, and may be 0.6 times the distance D2 or less. In the case where the plurality of through electrodes 13B are arranged in the Y direction, the gate-source capacitance Cgs is unlikely to increase because a distance between the wiring layers 14A and 14B is large. Thus, the distance D1 may be greater than or equal to the distance D2.

When the shortest distance D3 between the centers of the through electrodes 13A and 13B is long, the inductor L2 and the resistor R2 of the wiring layer 14A become large, and thus the source inductance Ls and the source resistance Rs are less likely to be reduced. From this viewpoint, the shortest distance D3 may be shorter than the minimum width D4 of the semiconductor chip 20. For example, when a planar shape of the semiconductor chip 20 is a rectangle, the minimum width D4 corresponds to a length of the short side of the rectangle. The shortest distance D3 may be 0.8 times the minimum width D4 or less, and may be 0.6 times the minimum width D4 or less.

A plurality of the reference potential pads 21, a plurality of the wiring layers 14A, a plurality of the through electrodes 13A, and a plurality of the through electrodes 13B are each provided so as to sandwich the amplifier 30. This can further reduce the source inductance Ls and the source resistance Rs, thereby further improving the high-frequency characteristics.

The example in which the amplifier 30 includes the transistor 32 having the source, the gate, and the drain has been described. In this case, the corner frequency fk can be increased by reducing the source inductance Ls and the source resistance Rs between the reference potential pad 21 and the base 10. Further, the maximum gain can be improved by providing the wiring layer 14D between the wiring layers 14B and 14C.

Even in the general amplifier 30, when the inductance and resistance connected to the reference potential of the amplifier 30 are large, the high-frequency characteristics are deteriorated. In addition, when the feedback capacitance of the amplifier 30 is large, the high-frequency characteristics are deteriorated. Thus, the amplifier 30 may include an element other than the transistor 32.

A lower surface (negative Z surface) of the base 10 is a reference potential surface to which a reference potential is supplied. In this case, in the second comparative embodiment, the source inductance Ls and the source resistance Rs are mainly the inductor L0 and the resistor R0 of the via wiring line 25, and become large. In the first embodiment, as illustrated in FIG. 7, the path 42 connected in parallel to the inductor L0 and the resistor R0 is connected, so that the source inductance Ls and the source resistance Rs can be reduced, and the high-frequency characteristics can be improved.

### Second Embodiment

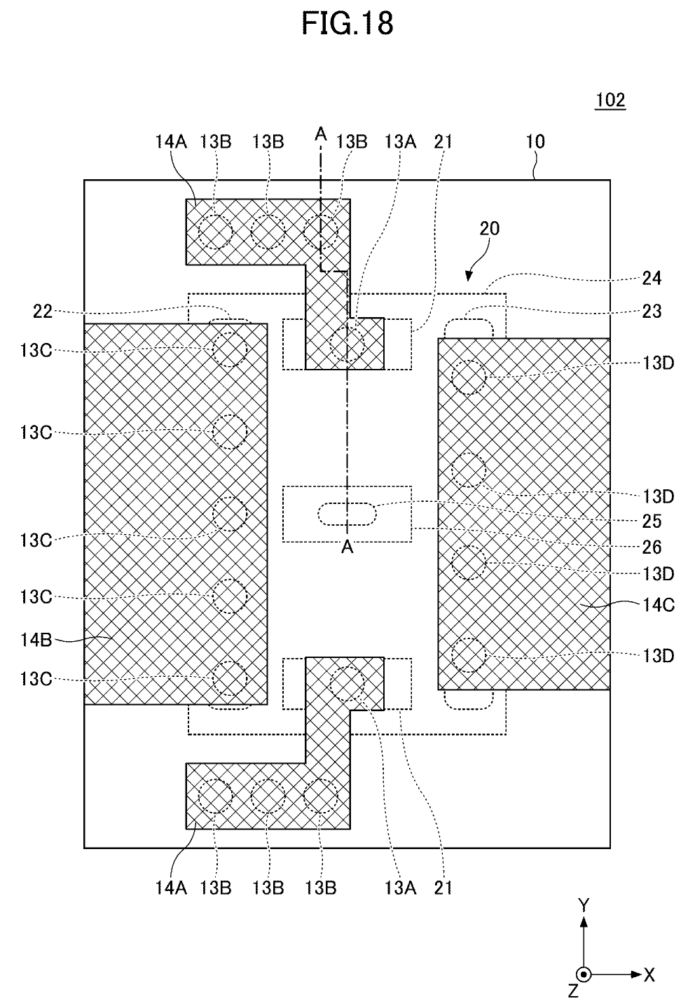

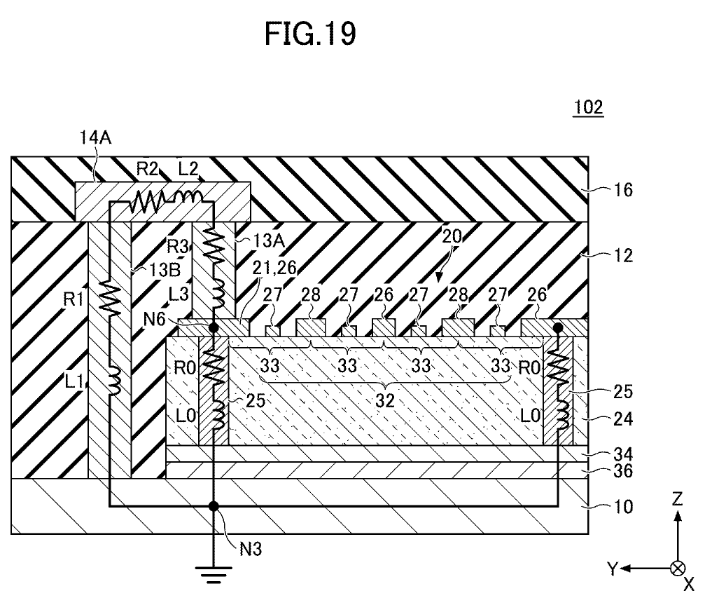

FIG. 18 is a cross-sectional view of a semiconductor device according to a second embodiment. FIG. 19 is a cross-sectional view taken along line A-A of FIG. 18. As illustrated in FIGS. 18 and 19, the wiring layer 14D is not provided in a semiconductor device 102 of the second embodiment. The other configurations are the same as those of the first embodiment, and the description thereof will be omitted.

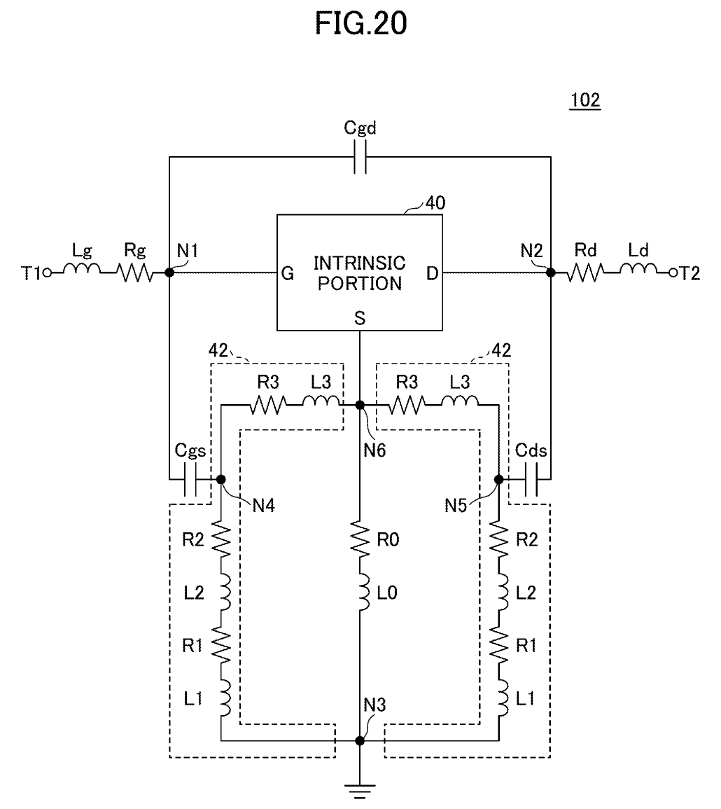

FIG. 20 is a circuit diagram illustrating an equivalent circuit of the semiconductor device according to the second embodiment. As illustrated in FIG. 20, in the semiconductor device 102 of the second embodiment, the inductor L4 or the resistor R4 is not connected between the nodes N4 and N5. Even in this case, the path 42 is connected between the source S and the ground in parallel with the inductor L0 and the resistor R0. This can reduce the source inductance Ls and increase the corner frequency fk. Thus, the high-frequency characteristics can be improved. In the semiconductor device 102 of the second embodiment, the gate-source capacitance Cgs is mainly a capacitance component between the wiring layers 14A and 14B. The drain-source capacitance Cds is mainly a capacitance component between the wiring layers 14A and 14C.

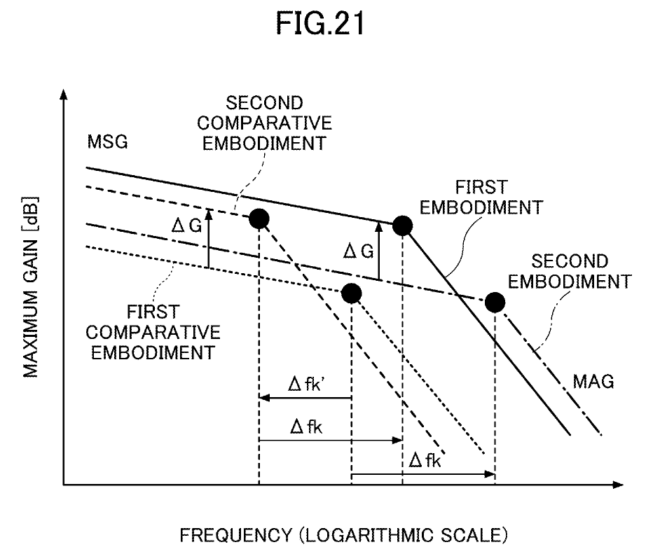

FIG. 21 is a schematic diagram illustrating the maximum gain with respect to a frequency in the embodiments and the comparative embodiments. As illustrated in FIG. 21, in a semiconductor device 112 of the second comparative embodiment provided with the wiring layer 14D, the MSG is improved by ΔG compared to the semiconductor device 110 of the first comparative embodiment. However, the corner frequency fk decreases by Δfk′. Thus, in the second comparative embodiment, the maximum gain is improved in the low-frequency region as compared with the first comparative embodiment, but the maximum gain is reduced in the high-frequency region.

Compared to the semiconductor device 112 of the second comparative embodiment, the semiconductor device 100 of the first embodiment is provided with the through electrode 13A. This can increase the corner frequency fk by Δfk in a state where the MSG is improved. Thus, the maximum gain in the high-frequency region can be made larger than that in the second comparative embodiment.

Compared to the semiconductor device 110 of the first comparative embodiment, the semiconductor device 102 of the second embodiment is provided with the through electrode 13A. This can increase the corner frequency fk by Δfk, although the MSG is not improved. Thus, the maximum gain in the high-frequency region can be made larger than that in the first comparative embodiment. As in the semiconductor device 102 of the second embodiment, the wiring layer 14D need not be provided.

In the first embodiment and the second embodiment, the frequency at which the maximum gain is larger than that in the second comparative embodiment and the first comparative embodiment is, for example, 0.1 GHz to 7 GHz, and 0.1 GHz to 6.5 GHz. Thus, when the center frequency of the operating band of the amplifier 30 is 0.1 GHz to 7 GHz, the maximum gain can be improved, and when the center frequency of the operating band of the amplifier 30 is 0.1 GHz to 6.5 GHz, the maximum gain can be further improved.

### Third Embodiment

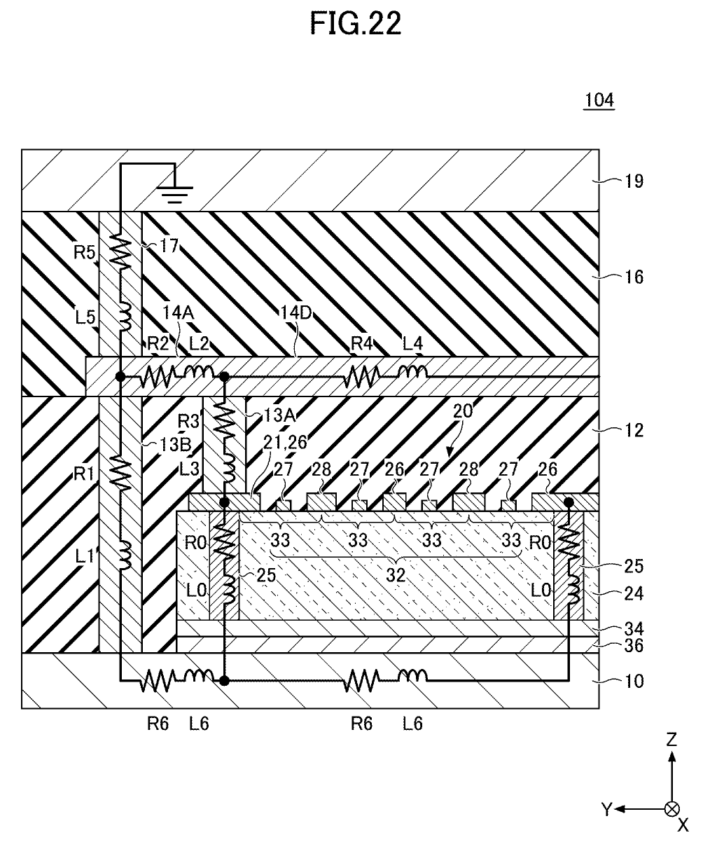

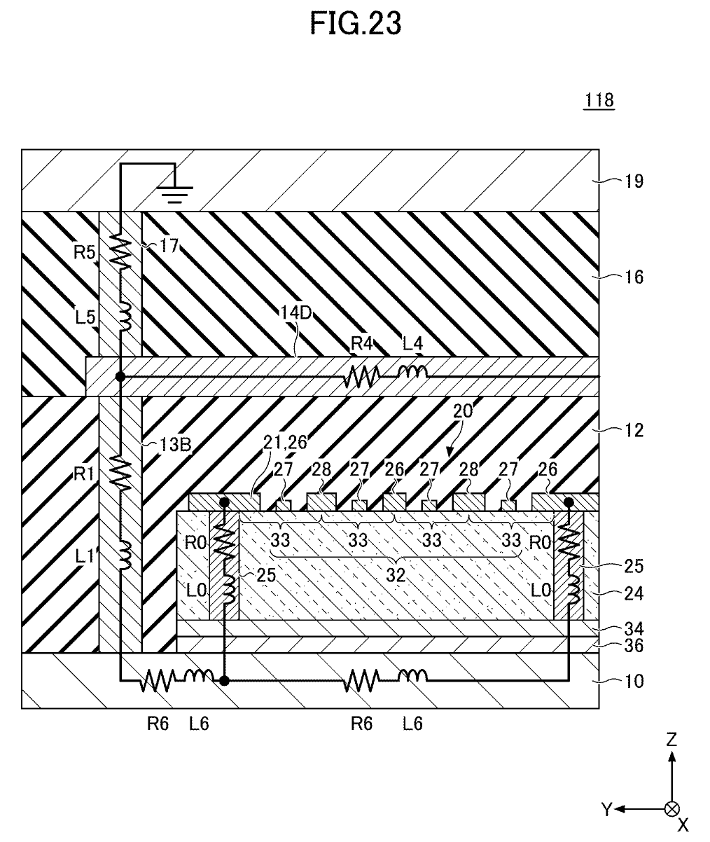

FIG. 22 is a cross-sectional view of a semiconductor device according to a third embodiment. As illustrated in FIG. 22, in a semiconductor device 104 of the third embodiment, a metal layer 19 is provided on the entire surface of the insulating layer 16 (second insulating layer). A through electrode 17 (fifth through electrode) penetrates the insulating layer 16 and electrically connects the wiring layer 14A to the metal layer 19. The metal layer 19 is a metal plate such as a copper plate. The through electrode 17 is a metal layer such as a copper layer. The other configurations are the same as those of the first embodiment, and the description thereof will be omitted.

### Fifth Comparative Embodiment

FIG. 23 is a cross-sectional view of a semiconductor device according to a fifth comparative embodiment. As illustrated in FIG. 23, the through electrode 13A is not provided in a semiconductor device 118 of the fifth comparative embodiment. The other configurations are the same as those of the third embodiment, and the description thereof will be omitted.

In the semiconductor device 118 of the fifth comparative embodiment, the lower surface (negative Z surface) of the base 10 is a heat dissipation surface that dissipates heat from the semiconductor chip 20, and a heat dissipation member such as a fin is connected. An upper surface (positive Z surface) of the metal layer 19 is a reference potential surface to which a reference potential is supplied. A path from the reference potential pad 21 to the reference potential surface includes the via wiring line 25, the base 10, and the through electrodes 13B and 17. An inductor L6 and a resistor R6 are provided as an inductance component and a resistance component in the base 10. The inductors L0, L6, L1, and L5 and the resistors R0, R6, R1, and R5 are connected in series in the path from the reference potential pad 21 to the reference potential surface. Thus, the source inductance Ls and the source resistance Rs become large, and the high-frequency characteristics are degraded.

In the third embodiment, the through electrode 13A is provided. As a result, in addition to a path in which the inductors L0, L6, L1, and L5 and the resistors R0, R6, R1, and R5 are connected in series, a path in which the inductors L3, L2, and L5 and the resistors R3, R2, and R5 are connected in series is added to a path from the reference potential pad 21 to the ground. Thus, the source inductance Ls and the source resistance Rs can be reduced, and the high-frequency characteristics can be improved.

In the third embodiment, the upper surface of the metal layer 19 is a reference potential surface to which a reference potential is supplied. Even in this case, the through electrode 13A is provided, so that the source inductance Ls and the source resistance Rs can be reduced, and the high-frequency characteristics can be improved.

Even in the case where the wiring layer 14D is not provided as in the second embodiment, the metal layer 19 and the through electrode 17 may be provided. The upper surface of the metal layer 19 may be the reference potential surface.

The embodiments disclosed herein are to be considered in all respects as illustrative and not restrictive. The scope of the present disclosure is defined by the appended claims rather than by the foregoing description, and all changes that come within the meaning and range of equivalency of the claims are intended to be embraced therein.

What is claimed is:

1. A semiconductor device comprising:
a base having an electrical conductivity;
a semiconductor chip mounted on the base, the semiconductor chip including a substrate, an amplifier provided at the substrate and configured to amplify a high frequency signal, a reference potential pad provided on an upper surface of the substrate and electrically connected to a reference potential terminal of the amplifier, and a via wiring line penetrating the substrate and electrically connecting the reference potential pad to the base;
a first insulating layer provided over the base so as to cover the semiconductor chip;
a first wiring layer provided on the first insulating layer;
a first through electrode penetrating the first insulating layer and electrically connecting the first wiring layer to the reference potential pad; and
a second through electrode penetrating the first insulating layer and electrically connecting the first wiring layer to the base.

2. The semiconductor device according to claim 1,
wherein the semiconductor chip further includes an input pad electrically connected to an input terminal of the amplifier and provided on the upper surface of the substrate, and an output pad electrically connected to an output terminal of the amplifier and provided on the upper surface of the substrate, and
wherein the semiconductor device further includes:
a second wiring layer provided on the first insulating layer;
a third wiring layer provided on the first insulating layer;
a third through electrode penetrating the first insulating layer and electrically connecting the second wiring layer to the input pad; and
a fourth through electrode penetrating the first insulating layer and electrically connecting the third wiring layer to the output pad.

3. The semiconductor device according to claim 2, further comprising:
a fourth wiring layer electrically connected to the first wiring layer and provided on the first insulating layer between the second wiring layer and the third wiring layer.

4. The semiconductor device according to claim 3,
wherein a distance between the fourth wiring layer and the second wiring layer is shorter than a distance between the fourth wiring layer and the third wiring layer.

5. The semiconductor device according to claim 3,
wherein an arrangement direction is a direction from the second wiring layer toward the third wiring layer, and
wherein a distance by which the first wiring layer protrudes from the fourth wiring layer in the arrangement direction is shorter than a distance by which the first wiring layer protrudes from the fourth wiring layer in a direction opposite to the arrangement direction.

6. The semiconductor device according to claim 2,
wherein a plurality of the reference potential pads, a plurality of the first wiring layers, a plurality of the first through electrodes, and a plurality of the second through electrodes are each provided so as to sandwich the amplifier.

7. The semiconductor device according to claim 2,
wherein the amplifier includes a transistor,
wherein the reference potential terminal is a source of the transistor,
wherein the input terminal is a gate of the transistor, and
wherein the output terminal is a drain of the transistor.

8. The semiconductor device according to claim 1,
wherein a shortest distance between the first through electrode and the second through electrode is shorter than a minimum width of the semiconductor chip.

9. The semiconductor device according to claim 1,
wherein the base has a lower surface that is a reference potential surface to which a reference potential is supplied.

10. The semiconductor device according to claim 1, further comprising:
a second insulating layer provided over the first insulating layer so as to cover the first wiring layer;
a metal layer provided on the second insulating layer; and
a fifth through electrode penetrating the second insulating layer and electrically connecting the metal layer to the first wiring layer.

11. The semiconductor device according to claim 10,
wherein the metal layer has an upper surface that is a reference potential surface to which a reference potential is supplied.
